(19) United States
(12) Patent Application Publication
(10) Pub. No.: US 2026/0313273 A1
(43) Pub. Date: Oct. 8, 2026

(54) RACK STANDARD INTERCHANGEABLE NETWORK SWITCH AND PATCH PANEL

(71) Applicant: Murat YILDIRIM, Aurora, CO (US)

(72) Inventor: Murat YILDIRIM, Aurora, CO (US)

(21) Appl. No.: 19/161,981

(22) PCT Filed: Sep. 1, 2023
(86) PCT No.: PCT/US2023/073299

§ 371 Date: Apr. 30, 2026

(51) Int. Cl. H04Q 1/02; H04Q 1/04; H05K 5/00

(52) U.S. Cl. CPC H04Q 1/13; H04Q 1/032; H04Q 1/04; H04Q 1/09; H04Q 1/155; H05K 5/0017

(57) ABSTRACT

A rack standard interchangeable network switch and patch panel includes a standardized case member insertable into a rack and securable in the rack without the need of screws or additional fasteners. A patch panel module and a network switch module are alternately insertable into an open front of the case member without a user having to first remove the case member from its position in the rack. Insertion of either module effectuates connection into network. At least one latch member on the network switch module effectuates seating of at least one power socket input into a corresponding power distribution unit installable in the rack when the latch member is moved to a second position. An auxiliary power supply unit is slidably installable and removable through a rear side of the case member even when the case member is installed to the rack. An SPF module is likewise installable.

### INCORPORATION BY REFERENCE

Pursuant to 37 C.F.R. § 1.57, this application for letters patent herein incorporates by reference the complete disclosure set forth in U.S. patent application Ser. No. 18/168,412 filed on 13 Feb. 2023 as if set forth fully herein.

### BACKGROUND OF THE INVENTION

Patch panels are traditionally employed for terminating horizontal or backbone cabling to be cross-connected from telecommunication outlets to other active equipment such as network switches or servers. Patch panels typically include termination ports on the rear side wherein cables can be punched down and transitioned from a cable to a female RJ45 outlet.

Further, patch panels are usually operated in such a manner as to physically exclude or preempt other hardware with respect to the location whereat the panel is installed. To change a network tower to include a network switch in lieu of a patch panel, then, typically requires deinstalling the patch panel and then reinstalling the network switch as complete, separate units. Typically, such action requires removal of fasteners and adaptation of the tower to accommodate the change, at least by requiring removal of a plurality of fasteners attachable in a first configuration to installation of another plurality of fasteners attachable in a second configuration. Further, network switches and patch panels may not be designed to occupy the same physical space and therefore may require additional spaces and slots in any network configuration in alternate configurations of the hardware. In other words, network switches and patch panels are not equivalent structural units interchangeable with a minimum of labor in mind.

The present invention solves the above problems by enabling employment of pre-terminated network cables connected to the patch panel wherein the need for field terminations is eliminated and installation of structured cabling systems is reduced by more than fifty percent. The present invention employs a case member that is slidably connectable into a rack by action of parallelly disposed sliding brackets and securable therein absent any separable fasteners such as screws or clips or typical fasteners seen in the art. Instead, the case member includes an open front into which either a network switch module or a patch panel module is insertable in the alternative, wherein interconnection of interior components is effectuated by securement of the respective module into the case member and the case member is secured into the rack when an anterior portion of either module when at least one latch member is moved from a first position to a second position. The network switch module includes a main board with a front touchscreen display for easy configuration, interchangeable power supplies for redundancy, and SFP modules for versatile connectivity.

The present invention, therefore, makes substituting a network switch with a patch panel, or vice versa, more efficient than systems currently seen in the art. A user simply releases the at least one latch member disposed on the anterior portion of the switch or panel by moving it back to the first position, enabling the respective module to be slid anteriorly out of the case member and decoupled therefrom. Simply sliding in the alternative module effectuates the necessary connections with cable connectors disposed rearwardly upon the case member and enables instant interconnection into network of either module. The result is a more efficient use of space and a more easily customizable network. Use with special cable connectors as set forth in U.S. patent application Ser. No. 18/168,412, which is hereby incorporated into this disclosure by reference in its entirety, further reduces the need for pre-terminated network cables and eliminates the need for field terminations and reduces installation of structured cabling systems by more than fifty percent. The novel combination of interchangeable network switch module and patch panel provides an integrated solution within a minimized amount of space and makes network management and connectivity easier and less complex while reducing cable clutter.

### FIELD OF THE INVENTION

The present invention relates to a rack standard interchangeable network switch and patch panel devised to enable efficient customization of network configurations by presenting a standard rack into which a case member secures and into which case member either a network switch module or patch panel module is insertable in the alternative, thereby allowing easy interchange of network components in the same rack.

Securement of the case member to the rack is effective when at least one latch member on the anterior portion of either module is moved from a first position to a second position. Installation of either module into the case member presents interconnection of interior components wherein connection into network is rendered immediate by the correct positioning of the said modules. No screws or other fasteners common to the art are required. Interconnection with power distribution units is automated when securing the modules into the case member. Small form-factor pluggable (“SFP”) modules are included and are configurable for fiber optic or standard RJ45 ports. Use with cable connectors with cascading termini, as set forth in U.S. patent application Ser. No. 18/168,412, which is hereby incorporated into this disclosure by reference in its entirety, is also contemplated herein whereby more efficient network configurations are enabled with less cabling and less rack customization.

### SUMMARY OF THE INVENTION

Network hardware is not rack standardized and is typically securable into rack structures via fasteners such as screws that inhibit easy interchange of components. Often, to switch out network hardware and replace it with alternative, mutually exclusive hardware, different rack configurations are required. Further, for security reasons, often doors or front panels or access to the fasteners themselves are restricted by locked components intended to prevent unauthorized removal or access to hardware or relevant components.

Further, most racks are devised for efficiently orienting hardware in stacks, to position a plurality of network hardware in space saving manner in vertical arrangements that present anterior and rear portions for access to front panels and rear jacks, sockets, and other interfaces or I/O ports. Openings in the rack structures may provide for access to such interfaces and I/O ports, however cables are often required to be employed independent of the racks themselves, whereby cabling is often grouped in clusters between various racks, towers, and network rooms. Thus, when engineering large networks, cabling can present spatial issues, requiring bundling, laying in certain and guided routes or tracks, and may take up unnecessary amounts of space.

The present rack standard interchangeable network switch and patch panel has been devised to enable interchangeable hardware readily installable into the same rack slot without the need for separable fasteners, such as screws, while allowing for reduced or consolidated cabling throughout the rack assembly due to automated connection with power distribution units, whereby individual power cables for each such hardware is eliminated. Further, increased bandwidth through a common cable is contemplated by the hardware where certain sockets are incorporated into the rack standard interchangeable network switch and patch panel, such as are set forth in U.S. patent application Ser. No. 18/168,412, which is incorporated in its entirety into this disclosure.

The instant rack standard interchangeable network switch and patch panel, as set forth herein, incorporates a case member devised to slidably engage interior to a rack. The case member may include means to slidably engage into a standardized slot in the rack, such as sliding brackets disposed widthwise on either end of the case member. Additional means of securing the case member into the rack are contemplated as within scope of this disclosure, as set forth herein and exemplified in the embodiments discussed below. The case member is devised to enable at least two configurations of hardware, a network switch module and a patch panel module. The case member includes an open front into which either the patch panel module or the network switch module is installable. Each module installable into the open front is standardized to fit interior to the case member, to connect with various sockets as required for operation, whereby an anterior portion disposed upon said each module is configured to enclosed the case member open front and seat the respective module securely in place. Once installed, movement of at least one latch member from a first position to a second position secures the respective module in position, and, in at least the case of the network switch panel, effectuates connection of the network switch module with power distribution units integrated with the rack by action of, in an example embodiment contemplated herein, a self-seating power socket input configured to be operationally extensible by action of the at least one latch member and seat into an associated power socket input in the rack when the latch member is secured to the second position. The rack may, therefore, be used to power all slots wherein modules are likewise installed, by a single power cord connecting the power distribution units disposed in the rack to a main power source, reducing the number of power cables required to connect with and supply power to each hardware module.

Further, at least the network switch module includes at least one data connector member configured to extend and connect into a corresponding socket member disposed on the rack whereby the said module is connectable into a network operationally communicating through the rack when the at least one latch member is moved to the second position. Once installed, therefore, the module is connectable immediately into network and may be accessed and configured remotely through network or via a suitable graphical user interface. In one example embodiment, at least the network switch module includes a graphical user interface, and/or touchscreen, on the anterior portion for direct access to control and configure the network switch module.

At least the network switch module also may include at least one auxiliary power supply unit connectable interior to the case member wherein at least the network switch module is powerable independent of the main power supply in the event of a power outage without the need of additional power cables exterior to the network switch module. In some embodiments contemplated herein, additional connectors are contemplated installed to or operationally coupled with the case member, including, in an example embodiment contemplated here, at least one small-factor pluggable module.

The present rack standard interchangeable network switch and patch panel, therefore, enables rapid switching of hardware modules within the same rack such that a network configuration is more easily rendered. Network switches and patch panels are interchangeable, and easily swapped by deinstalling one and installing the other, simply by manual action of the at least one switch member. Cabling, consistently a problem for large networks due to the quantity of cables required to patch hardware into network, is minimized. Each rack unit may be connected to a single power line that then distributes power internally through the rack for instant connection with each said rack standard interchangeable network switch and patch panel as is installed in each rack. A more permanent configuration of racks, therefore, may be more efficiently utilized between different configurations without having to alter the rack configurations to accommodate the change. More efficient network design and maintenance is therefore afforded by the present invention, which is more particularly set forth and described by way of example embodiments in the accompanying detailed description.

Thus, has been broadly outlined the more important features of the present rack standard interchangeable network switch and patch panel so that the detailed description thereof that follows may be better understood and in order that the present contribution to the art may be better appreciated.

Objects of the present rack standard interchangeable network switch and patch panel, along with various novel features that characterize the invention are particularly pointed out in the claims forming a part of this disclosure. For better understanding of the rack standard interchangeable network switch and patch panel, its operating advantages and specific objects attained by its uses, refer to the accompanying drawings and description.

### BRIEF DESCRIPTION OF THE DRAWINGS

Figures

FIG. 1 is an raised elevation view of an example embodiment of patch panel model installed to a rack.

FIG. 2 is an elevation view of an example embodiment of a case member having an open front.

FIG. 3 is an elevation view of an example embodiment of a patch panel module insertable interior to the case member through the open front.

FIG. 4 is an elevation view of an example embodiment of the patch panel module about to secure into the case member by engagement with the open front and interconnection with circuitry connecting the patch panel module with ports connecting to network at rear of the case member.

FIG. 5 is an elevation view of an example embodiment of the case member with the patch panel module installed.

FIG. 6 is a front elevation view of an example embodiment of the patch panel being removed (or inserted) into the case member when the case member is installed to a rack without a user having to remove the case member to remove the patch panel module.

FIG. 7 is a side elevation view of an example embodiment of the patch panel disengaging from connection interior to the case member for easy removal from the case member, whether the case member is installed to a rack member or not.

FIG. 8 is a side elevation view of an example embodiment of a network switch module inserting into the case member via the open front.

FIG. 9 is a side elevation view of an example embodiment of the network switch module about to secure into the case member with the top of the case member removed for viewing of the interior.

FIG. 10a is a rear diagonal elevation view of an example embodiment of the network switch module installed interior to the case member with a top removed for viewing the interior, wherein an auxiliary power supply module is insertable through the rear of the case member for redundant power.

FIG. 10b is a detail rear diagonal elevation view of an example embodiment of the network switch module installed interior to the case member with the auxiliary power supply about to engage in connection with the network switch by action of a quick release mechanism.

FIG. 11a is a rear elevation view of an example embodiment of the network switch module installed interior to the case member with an SFP module insertable into connection with the network switch module through the rear of the case member.

FIG. 11b is a detail rear diagonal elevation view of an example embodiment of the network switch module installed interior to the case member with the SFP module about to engage in connection with the network switch by action of a quick release mechanism.

FIG. 12 is a front diagonal elevation view of an example embodiment of the case member with network switch module installed and about to secure into a rack member by action of latch members securing the case member into the rack without the need for screws or other fasteners while simultaneously engaging self-seating power socket inputs into corresponding power distribution units installable into the rack.

FIG. 13 is a front diagonal elevation view of an example embodiment of the case member with network switch module installed and about to secure into a rack member by action of latch members securing the case member into the rack while simultaneously engaging self-seating power socket inputs into corresponding power distribution units installable into the rack.

FIG. 14 is a front diagonal elevation view of an example embodiment of the case member with network switch module installed secured to the rack.

FIG. 15 is a front diagonal elevation view of an example embodiment of the case member installed to the rack whereby the network switch module has been removed and the patch panel module is about to be inserted into the case member for immediate interconnection with network without having to remove the case member.

FIG. 16 is an exploded top elevation view of an example embodiment of a latch member by which the network switch module secures through the case to the rack and plants self-seating power socket inputs into adjacent power distribution units housed by the rack when the corresponding latch member is moved from the first to the second position.

FIG. 17 is a rear diagonal elevation view of an example embodiment of the latch member.

FIG. 18 is an exploded front diagonal elevation view of an example embodiment of the latch member wherein a network jack is seated into network connection adjacent the self-seating power socket input when the latch member is moved from a first position to a second position.

FIG. 19 is a front diagonal elevation view of an example embodiment of the latch member wherein a network jack is seated into network connection adjacent the self-seating power socket input when the latch member is moved from a first position to a second position.

FIG. 20 is a rear diagonal elevation view of an example embodiment of the latch member wherein a network jack is seated into network connection adjacent the self-seating power socket input when the latch member is moved from a first position to a second position.

FIG. 21 a top elevation view of an example embodiment of the latch member wherein a network jack is seated into network connection adjacent the self-seating power socket input when the latch member is moved from a first position to a second position.

### DETAILED DESCRIPTION OF THE DRAWINGS

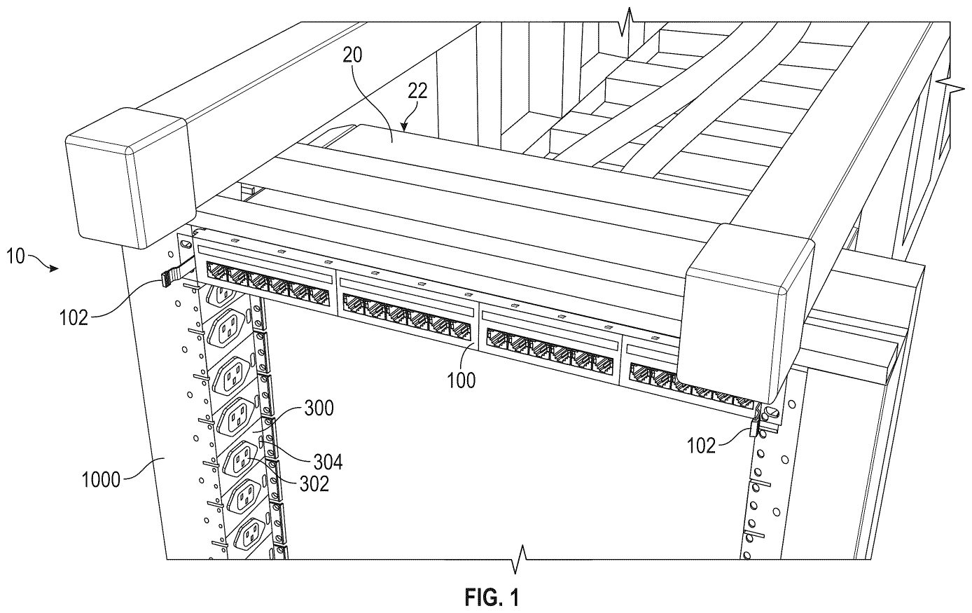

With reference now to the drawings, and in particular FIGS. 1 through 21 thereof, example of the instant rack standard interchangeable network switch and patch panel employing the principles and concepts of the present rack standard interchangeable network switch and patch panel and generally designated by the reference number 10 will be described.

FIG. 1 shows a diagonal front elevation view of the rack standard interchangeable network switch and patch panel 10 installed to rack 1000. In this example embodiment, patch panel module 100 has been installed into case member 20, and is secured therein by action of quick release mechanisms 102. No screws or other fasteners are required to secure patch panel module 100 or case member 20 into rack 1000.

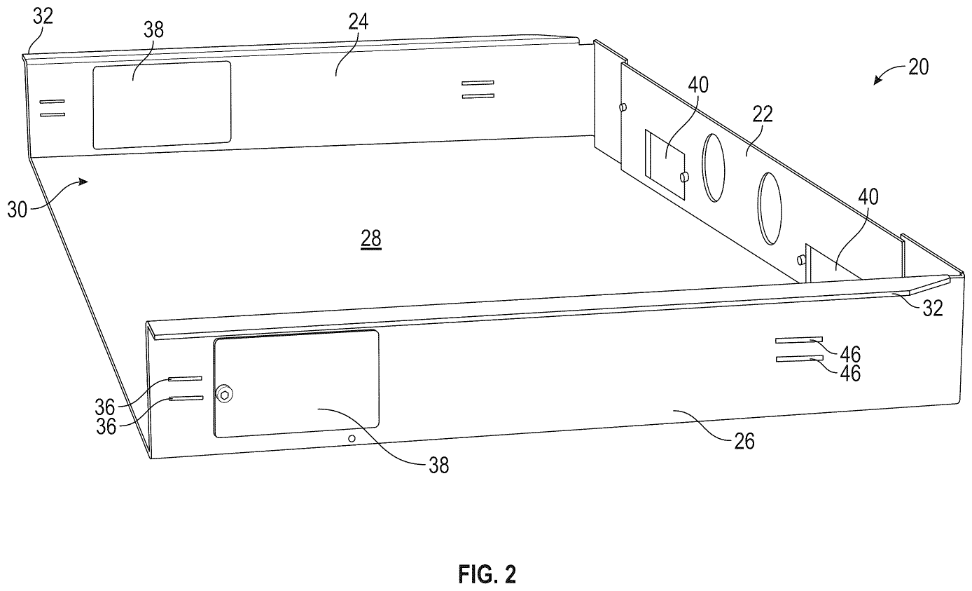

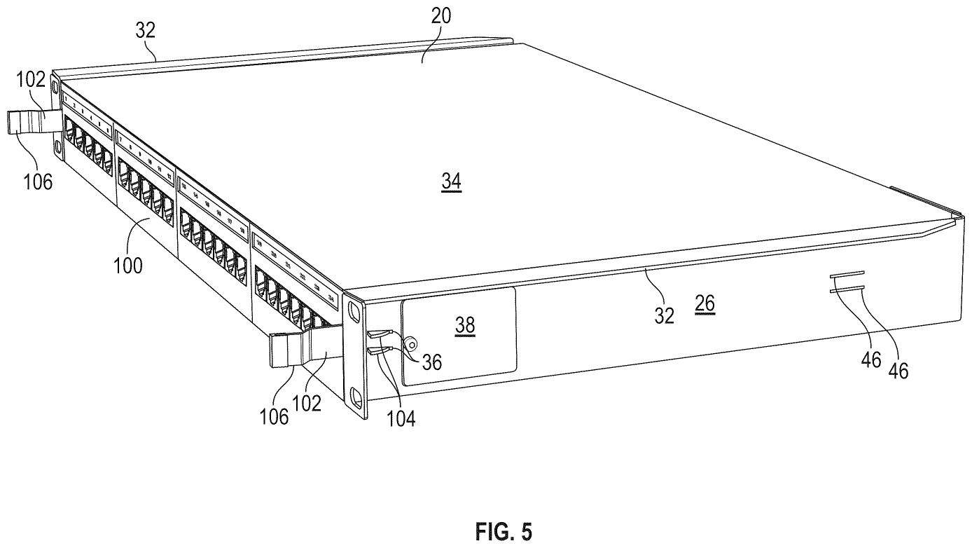

FIG. 2 shows a diagonal side elevation view of an example embodiment of case member 20 with a top portion removed for the purposes of illustration. Case member 20 includes rear side 22, left side 24, right side 26, base 28, and open front 30. Case member 20 top is not shown for the purposes of illustration (see FIG. 5 for an example embodiment of case member 20 with patch panel module 100 installed). Lateral flange portion 32 is disposed at top of left side 24 and right side 26 by which case member 20 slidingly engages into rack 1000.

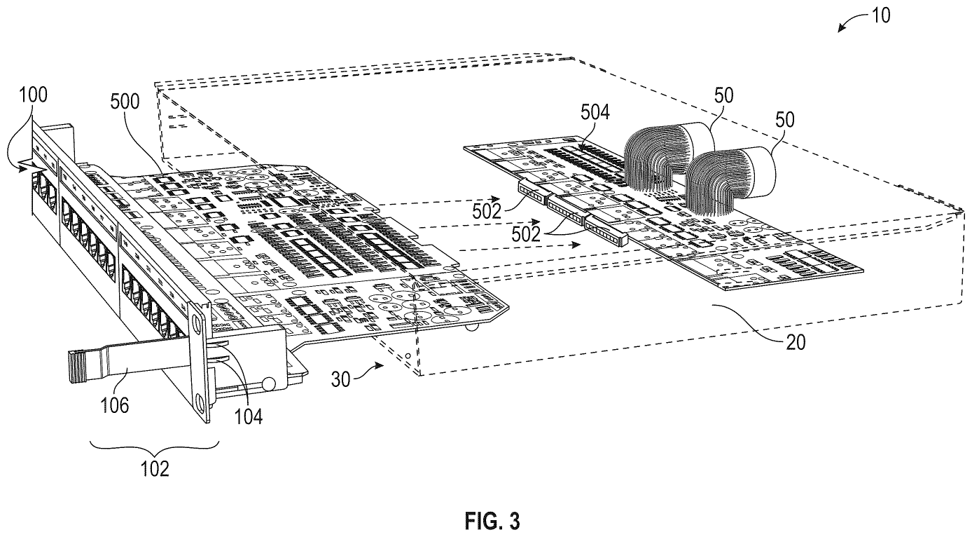

FIG. 3 shows a diagonal side elevation view of an example embodiment of patch panel module 100 inserting into case member 20 open front 30. Circuitry 500 of patch panel 20 releasably secures into connection ports 502 of port circuitry 504 installable at rear of case member 20 whereby patch panel module 100 is connectable into network by insertion into case member 1000. Port circuitry 504 may connect with ports devised for connection with cable connectors as set forth in U.S. patent application Ser. No. 18/168,412. Port circuitry 504 is installable and customizable whereby automated interconnection with network ports seen in the art is also contemplated as within scope of this disclosure. Such network ports may include, but are not intended to be limited to, existing ports for network communication such as, for example, jacks used with CAT6; CAT5; CAT5e cables; RJ45 jacks; RL6 jacks; and other jacks used or useable for connection to network.

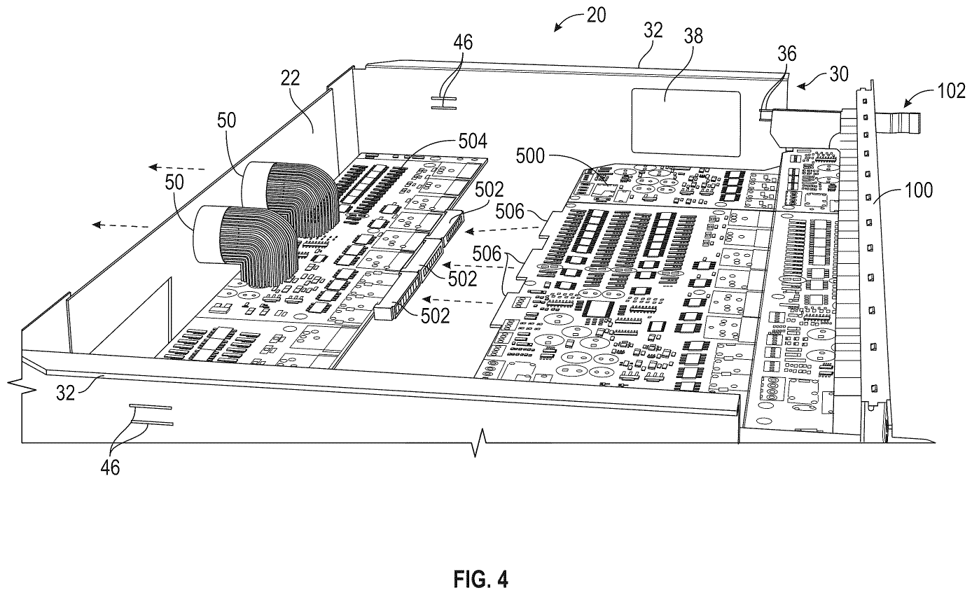

FIG. 4 shows a diagonal side elevation view of an example embodiment of patch panel module 100 about to secure into position through open front 30 of case member 20. Quick release mechanisms 102 engage with right and left sides 24, 26 at open front 30. Patch panel circuitry 500 inserts connection tabs 506 into connection ports 502 disposed on port circuitry 504 for instant connection with network jacks when connected to network ports 50 disposed on rear side 22 of case member 30.

FIG. 5 shows a side elevation view of an example embodiment of patch panel module 100 installed interior to case member 20. In this view, case member 20 top 34 is included. In some embodiments, top 34 may secure over lateral flange portions 32. In this example embodiment, quick release mechanisms 102 engage stop members 104 into slots 36 in respective case member 20 right and left sides 24, 26. Quick release mechanisms 102 include arms 106 which, when pushed toward each other, release stop members 104 from engagement with case member 20 whereby patch panel module 100 may be slidingly removed from interior to case member 20 through open front 30 and exchanged for network switch module 200, as will be discussed further herein below.

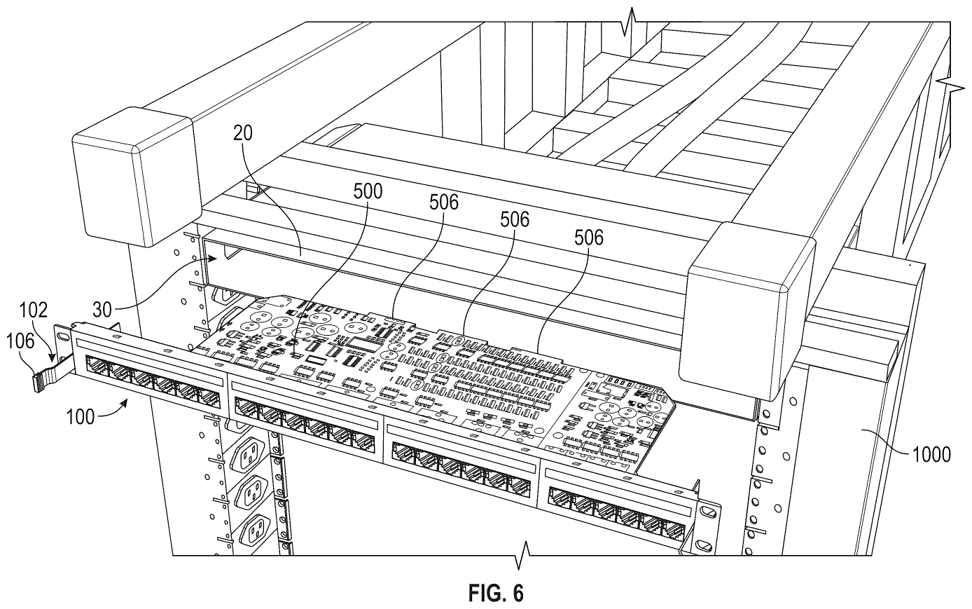

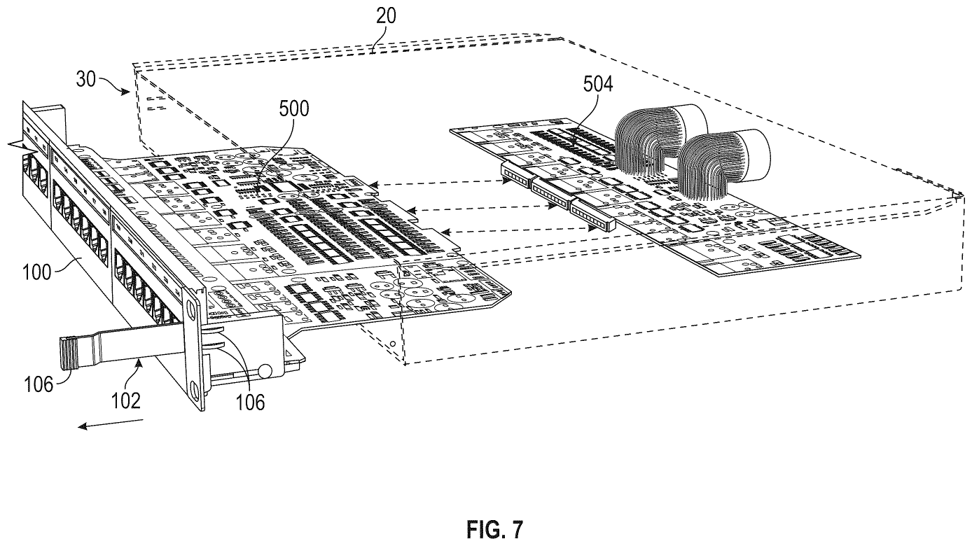

It should be noted that case member 20 may slidingly position interior to rack 1000 along lateral flange portions 32 and no additional fasteners are necessary. Thus, case member 20 can be rapidly installed to rack 1000 at a desired position in network or network hub and, as shown in FIG. 6 and FIG. 7, patch panel module 100 may be easily replaced, removed, or switched out for network switch module 200 by removal through case member 20 open front 30 when quick release mechanisms 102 are manipulated, without a user having to first unscrew and remove case member 20.

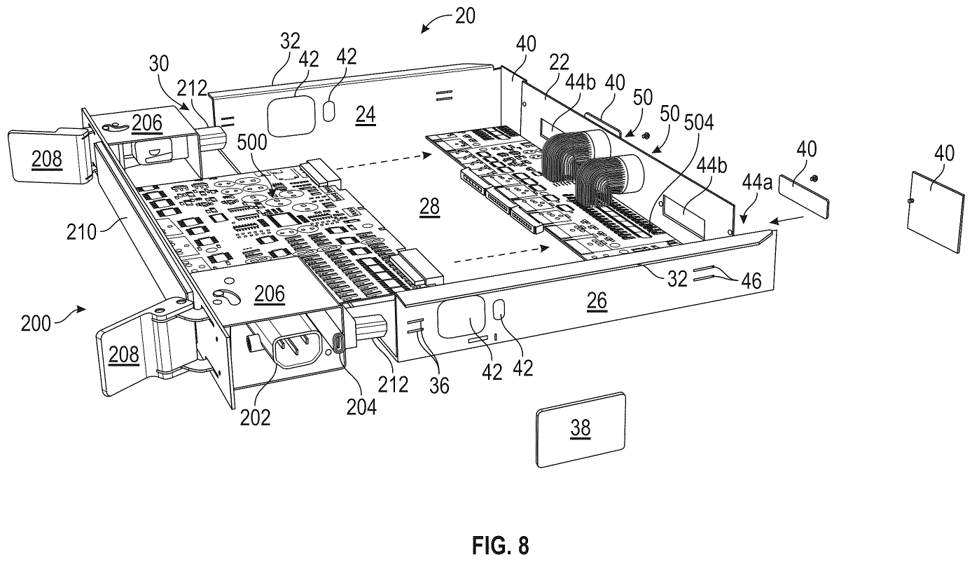

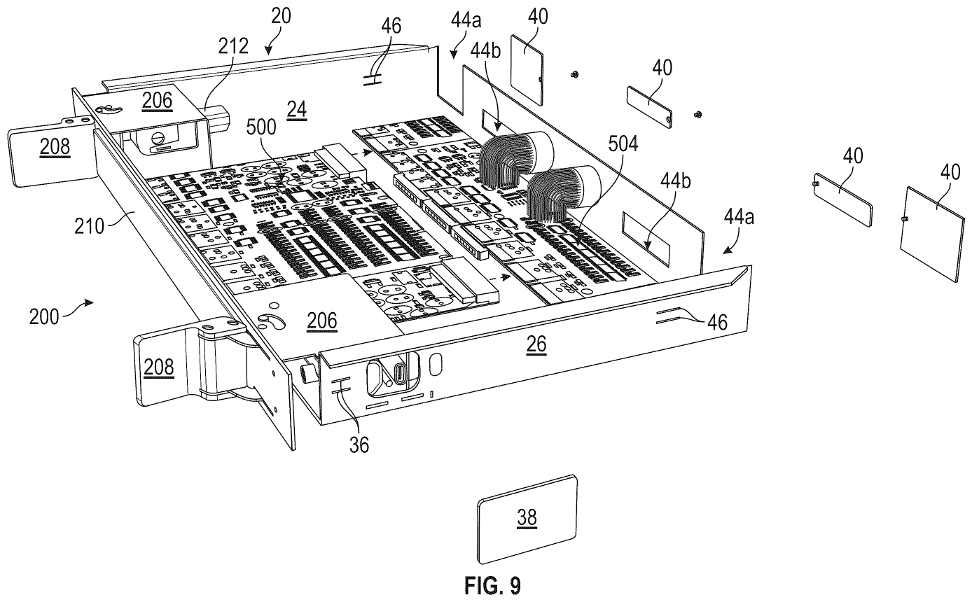

FIGS. 8 and 9 show diagonal side elevation views of an example embodiment of network switch module 200 slidingly positional interior to case member 20, through case member 20 open front 30. In this example embodiment, side panels 38 are removable to accommodate seating of power socket input 202 and data connector 204 (when present), here exemplified as a USB-C jack, which are extendible from socket boxes 206. Rear panels 40 are removable to accommodate seating of separable power supplies 400 (for AC to DC conversion and to maintain redundant power conformant with Tier 1 uptime standards), and SFP modules 600, as will be described herein below.

In this example embodiment, installation of network switch module 200 is effectuated by sliding network switch module 200 into case member 20 open front 30 and engaging latch members 208 from a first position to a second position. When latch members 208 are moved to the second position, power socket input 202 and data connector 204 are extended from socket boxes 206 through case member 20 side openings 42 to connect with power distribution unit 300 housing power sockets 302 and network connector sockets 304 respectively installed in rack 1000. Note that case member 20 is customizable-both right and left sides 24, 26 of case member 20 may be used in conjunction with socket boxes 206 depending on the desired rack configuration. In this example embodiment, network switch module 200 incorporates touchscreen front 210, which encloses case member 20 open front 30 when network switch module 200 is installed.

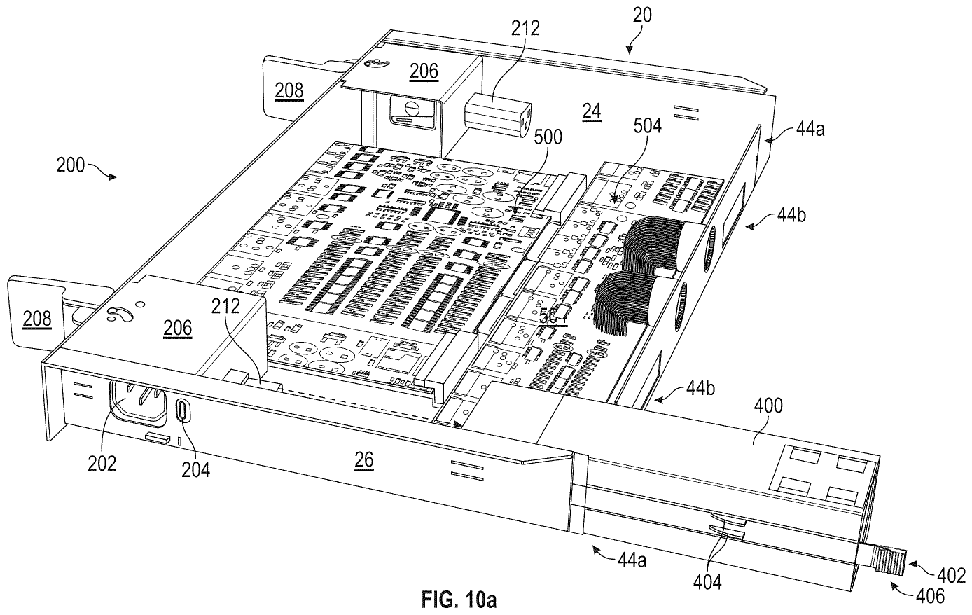

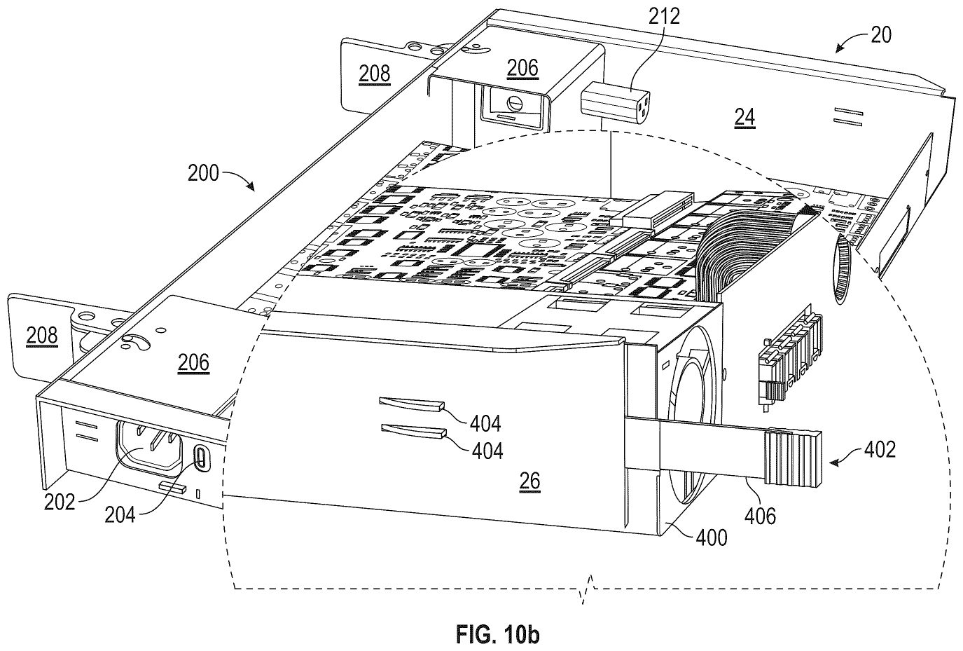

FIG. 10a shows a raised side elevation view of case member 20 with top removed for purposes of illustration of the network switch module 200 installed therein. In this example embodiment, auxiliary power supply 400 is installable through rear opening 44a by sliding therethrough. Auxiliary power supply 400 seats into operational communication with network switch module 200 when fully inserted into network switch module 200 by matingly engaging with power socket input 212 disposed rear facing on socket box 206. Quick release mechanism 402 enables rapid deployment and replacement of auxiliary power supply 400 without a user having to remove case 20 member from rack 1000. Since separable power supplies frequently are the main point of failure for network switches in operation, such a configuration enables increased efficiency in network maintenance and configuration. No screws of other fasteners are required and auxiliary power supply 400 is easily installed, removed, and switched out for new auxiliary power supply independent of case member 20 position, installed in rack 1000 or removed therefrom.

FIG. 10b is a detail view of an example embodiment of quick release mechanism 402 operative on auxiliary power supply 400. When auxiliary power supply 400 is fully inserted through rear opening, stop members 404 engage through slots 46 on case member 20 left side 24. Stop members 404 are curved to facilitate travel of the auxiliary power supply 400 into case member 20, but present a right angular surface to prevent removal of the auxiliary power supply 400 therefrom until quick release 402 lever arm 406 is manipulated to disengage stop members 404.

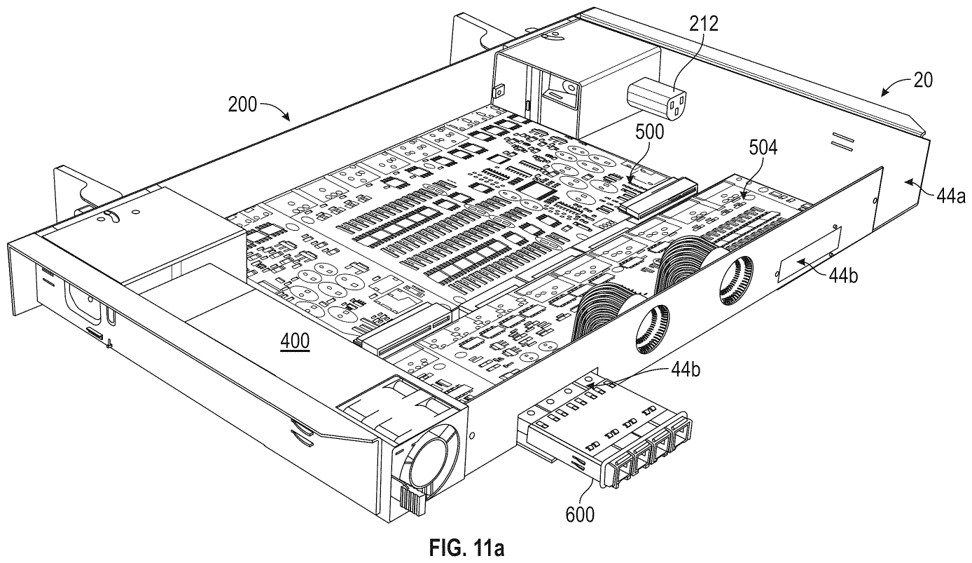

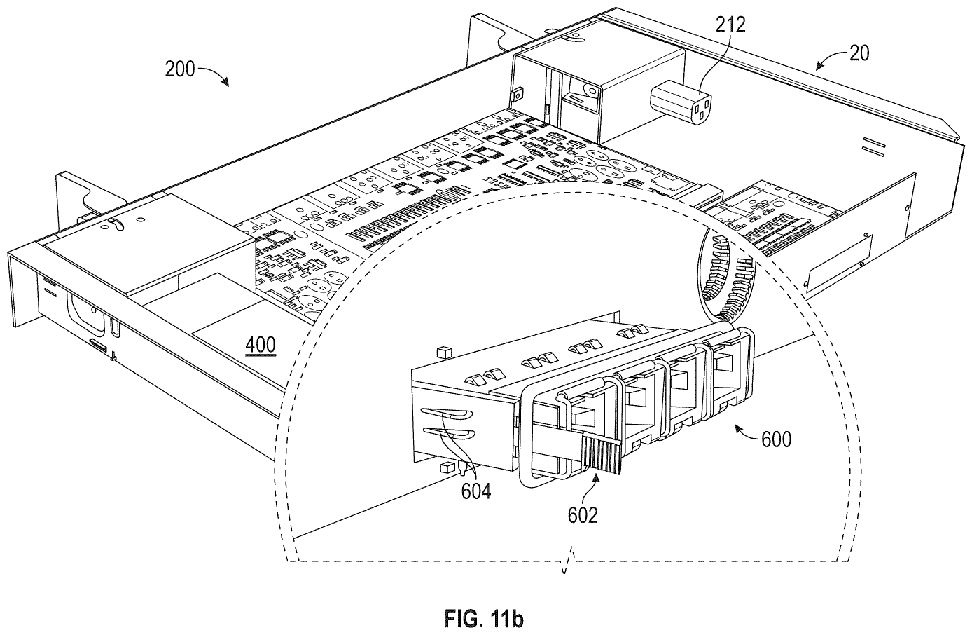

FIG. 11a shows a raised rear diagonal elevation view of an example embodiment of case member 20 with top removed for purposes of illustration of the network switch module 200 installed therein. In this example embodiment, SFP module 600 is installable through rear opening 44b by sliding therethrough. As shown in the detail view of the example embodiment in FIG. 11b, stop members 604 prevent removal of SFP module 600 from rear opening 44b unless quick release mechanism 602 is first manipulated to disengage stop members 604 from obstructing removal. Inserting SPF module 600 into rear opening 44b seats SFP module 600 into connection with circuitry 500 interior to case member 20. Thus, SFP module 600 can be easily installed and removed independent of case member 20, whether case member 20 is installed or removed from rack 1000, in like capacity as auxiliary power supply 400.

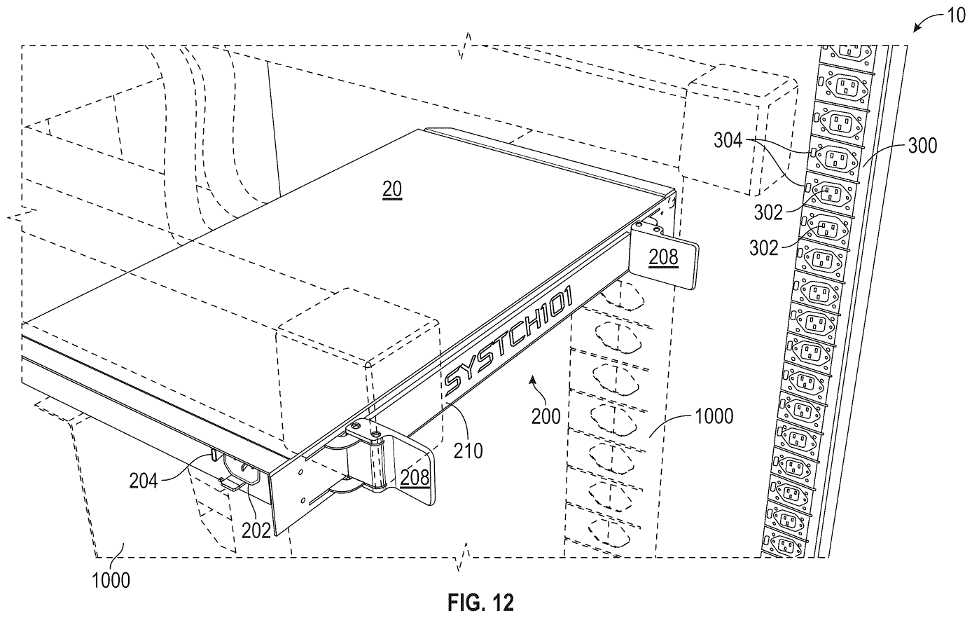

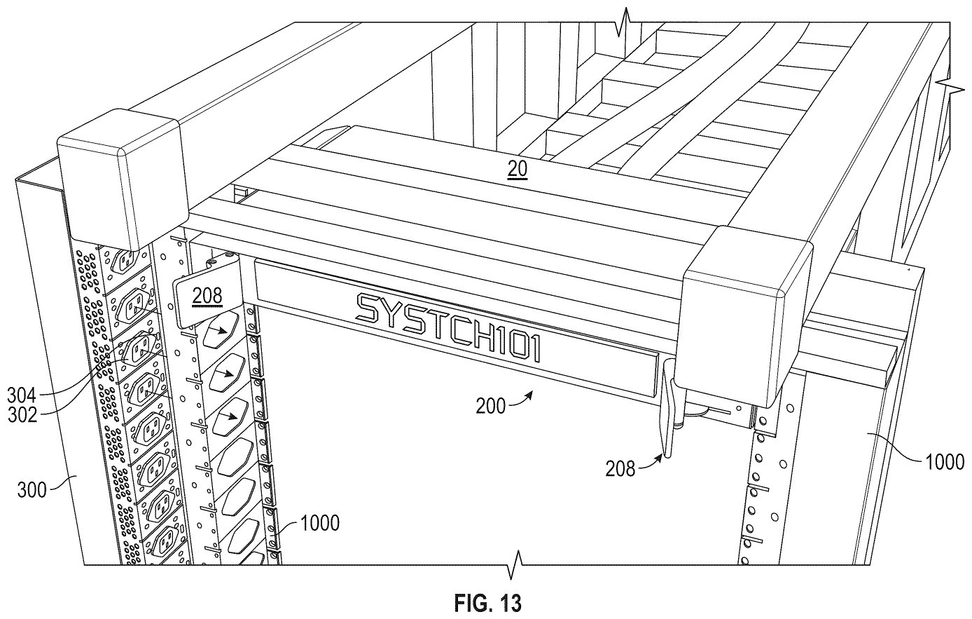

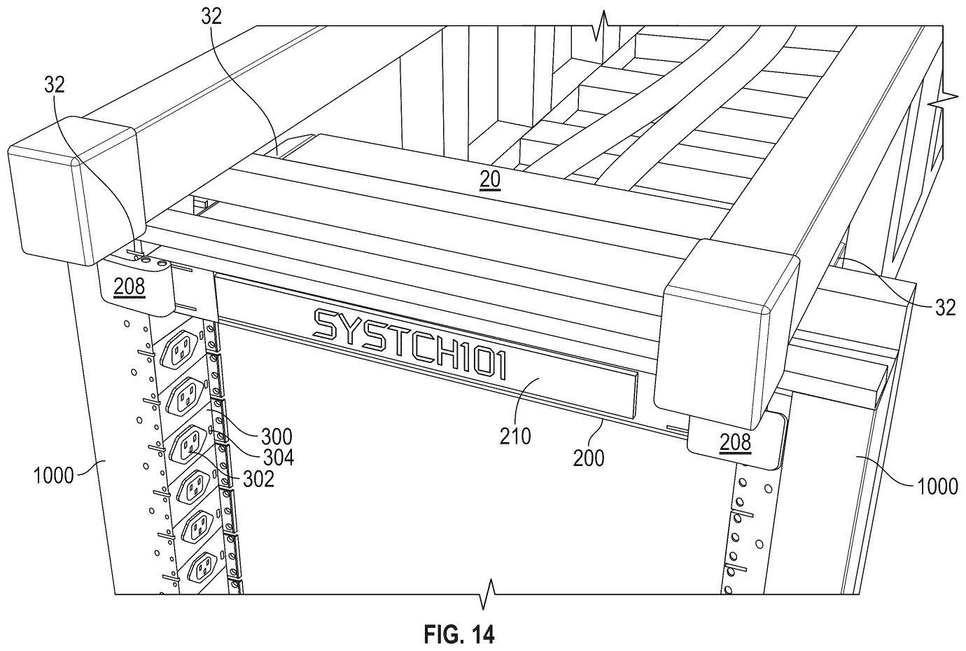

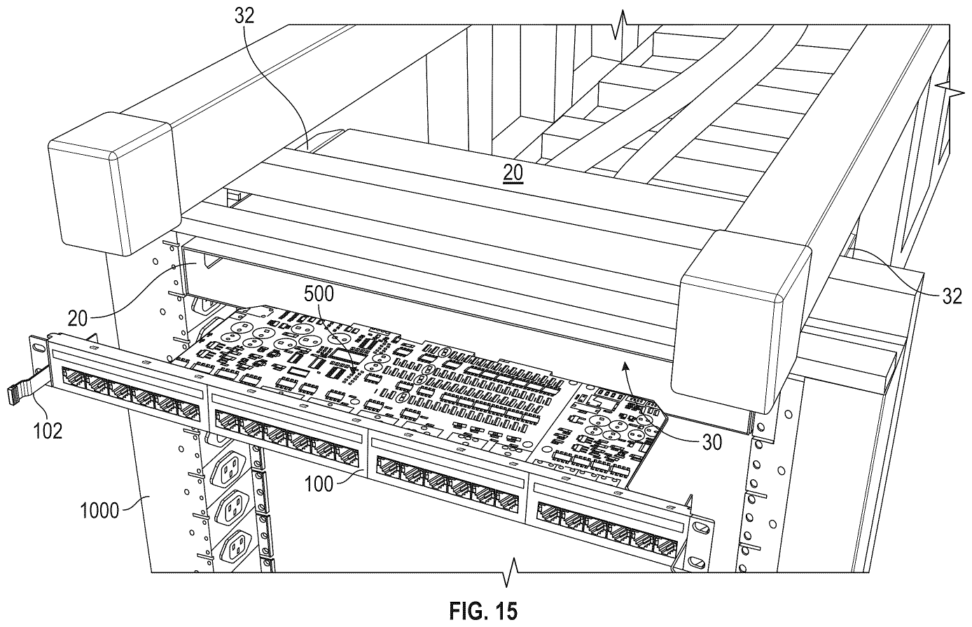

FIG. 12 shows a diagonal front elevation view of an example embodiment of case member 20 with network switch module 200 installed seated into rack 1000. Power distribution unit 300 is installable at right side of rack 1000 in vertical configuration to position respective power socket 302 and network connection socket 304 (or other network port) for interconnection with power socket input 202 and data connector 204 (here exemplified as a USB-C jack, or other network communication jack) of network switch module 200 when corresponding latch member 208 is moved to the second position whereby power socket input 202 and data connector 204 (USB-C jack or other network communication jack) are extended to interconnect with power distribution unit 300 respectively. Similarly, FIG. 13 shows a diagonal front elevation view of an example embodiment of case member 20 with network switch module 200 installed seated into rack 1000 with latch members 208 partially moved toward the second position. Power distribution units 300 are installable on either side of rack 1000, in vertical configuration, to position power sockets 302 in rack 1000 sides at the correct locations for interconnection with network switch modules 200 installed in case members 20 and slid into corresponding positions in rack 1000. FIG. 14 shows a diagonal front elevation view of an example embodiment of case member 20 with network switch module 200 installed secured to rack 1000 by action of each lateral flange portion 32 sliding into rack 1000 and action of latch members 208 engaging into power distribution units 300 installed to rack 1000 sides. FIG. 15 is included to show the ease by which network switch module 200 may be removed from case member 20 and patch panel module 100 inserted into case member 20 in lieu of network switch module 200 without a user having to uninstall case member 20 or contend with any fasteners other than latch members 208 and/or quick release mechanisms 102.

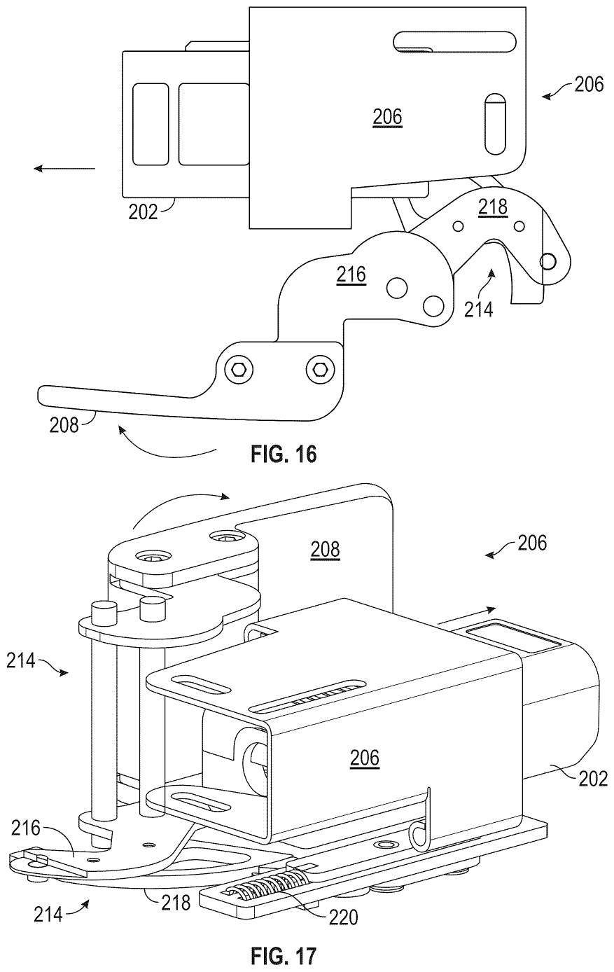

FIG. 16 is a detail top elevation exploded view of an example embodiment of socket box 206 illustrative of the mechanism by which latch member 208 operates to extend power socket input 202 to an extended position when latch member 208 is moved to the second position. Double-hinge mechanism 214 translates pivotal motion of latch member 208 from first position to second position into linear motion of power socket input 202 from nonextended position to extended position. FIG. 17 is a rear diagonal elevation view of an example embodiment of socket box 206 with latch member 208 moved to the second position wherein power socket input 202 is disposed in the extended position. As is shown in FIG. 17, when latch member 202 is moved to the first position, first pivotal leaf member 216 of double-hinge mechanism 214 is pulled outward, away from socket box 206 whereby second pivotal leaf member 218 is pulled away from socket box 206 and power socket input 202 is retracted. Action of double-hinge mechanism 214 may compress spring member 220 when latch member 208 is moved to the first position, thereby biasing latch member 208 in the second position and socket power input 202 in the extended position.

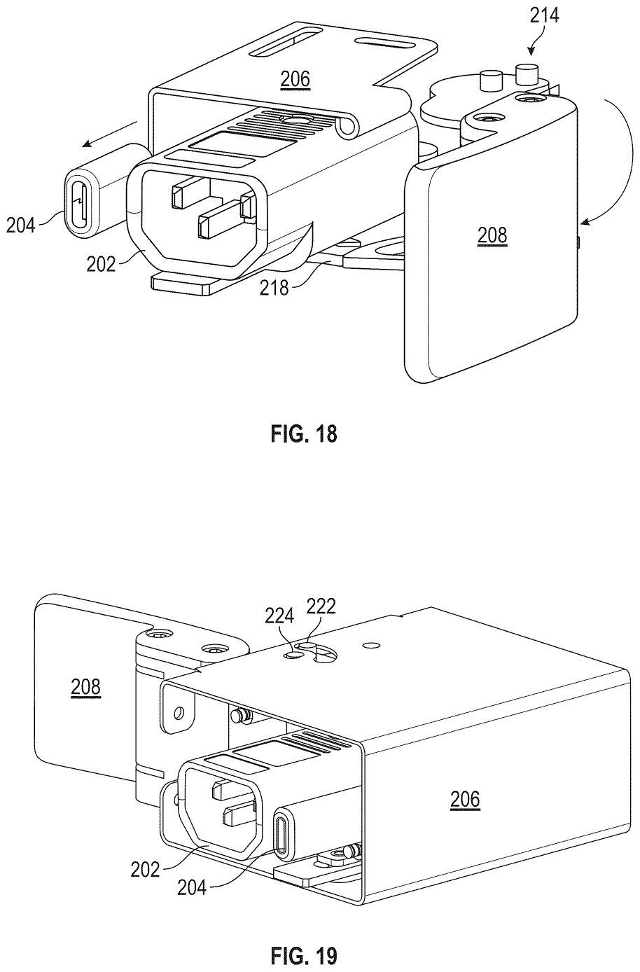

FIG. 18 shows a front diagonal elevation view of an example embodiment of socket box 206 having power socket input 202 and data connector 204 extensible when latch member 208 is moved to the second position (as shown). Data connector 204 is exemplified as a USB-C jack, and included for example only, any additional or other port may likewise be configured with latch member 208 whereby extension into networked communication with a network is enabled operationally communicating through or to rack 1000 or power distribution unit 300 (as shown herein).

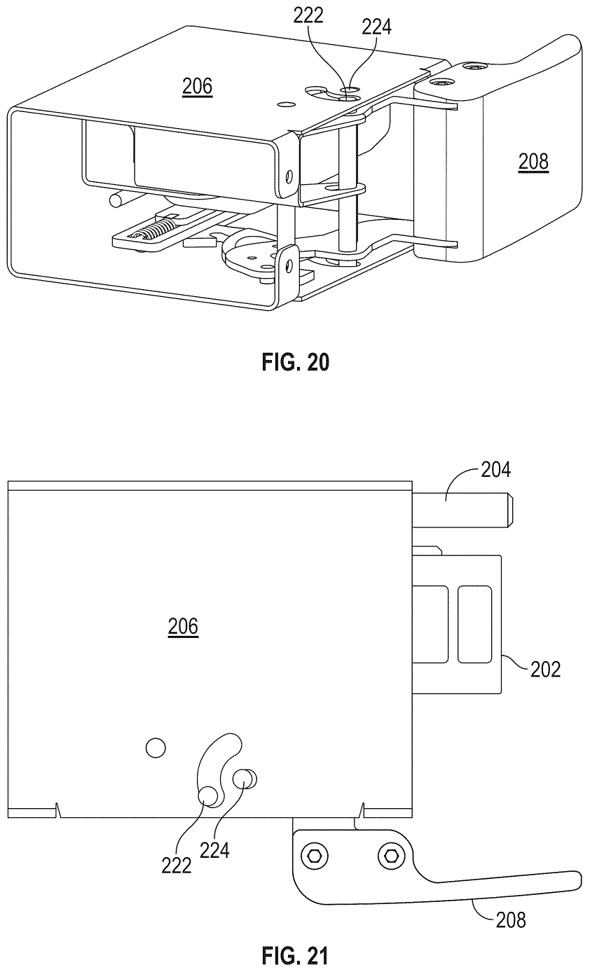

FIG. 19 shows a front diagonal elevation view of an example embodiment of socket box 206 with latch member 208 disposed in the first position whereby power socket input 202 and data connector 204 are disposed in the nonextended position. FIG. 20 shows a rear diagonal elevation view of an example embodiment of socket box 206 with the latch member 208 disposed in the second position. Spring member 220 is uncompressed. FIG. 21 shows a top elevation view of an example embodiment of socket box 206 with latch member 208 disposed in the second position. Lock member 222 may be included to prevent inadvertent removal of case member 20; release means 224 is included which, when depressed or manipulated between at least a first position and a second position, enables lock member 222 to be released whereby latch member 208 is restorable to the first position to retract power socket input 202 and data connector 204 interior to socket box 206 for the purposes of removing network switch module 200 from case member 20.

Thus, the instant rack standard interchangeable network switch and patch panel 10 enables installation of a standardized case member 20 into standardized rack 1000 having a plurality of rack positions, whereby configuration of a network in a network hub is facilitated. Network switch modules 200 and patch panel modules 100 are hot-swappable. Networks can be configured and reconfigured in significantly less time than is seen with hardware current in the art. No fasteners are required, each component is removable and installable independently, whether case member 20 is installed to a rack 1000 position or not.

What is claimed is:

1. A rack standard interchangeable network switch and patch panel comprising:
a case member slidably connectable to a rack, said case member having an open front;
a network switch module insertable into the open front, said network switch module having an anterior portion configured to close the open front wherein the network switch module is securable interior to the case member when at least one latch member is moved from a first position to a second position; and
a patch panel module insertable into the open front in lieu of and in the alternative to the network switch module, said patch panel having an anterior portion configured to close the open front whereby the patch panel module is securable into the case member when at least one quick release member is moved from a first position to a second position;
wherein the case member is secured to the rack when the at least one latch member of the network switch module or the quick release mechanism of the patch panel module is moved from the first to the second position whereby the case member is securable in rack position without the need of screws or other fasteners.

2. The rack standard interchangeable network switch and patch panel of claim 1 wherein the network switch module includes at least one self-seating power socket input disposed to extend and connect into a corresponding power distribution unit disposed within the rack when the latch member is moved from the first position to the second position whereby moving the latch member to the second position plugs the network switch module into the power distribution unit.

3. The rack standard interchangeable network switch and patch panel of claim 2 wherein the network switch module further includes a data connector member disposed to extend and connect into a corresponding socket member disposed on the rack whereby the network switch module is connectable into a network communicating through the rack when the latch is moved from the first position to the second position.

4. The rack standard interchangeable network switch and patch panel of claim 1 wherein the case member includes sockets rearward for interconnection with cable connectors set forth in U.S. patent application Ser. No. 18/168,412.

5. The rack standard interchangeable network switch and patch panel of claim 3 wherein the network switch module includes a touchscreen.

6. The rack standard interchangeable network switch and patch panel of claim 5 wherein the network switch module includes at least one auxiliary power supply unit slidably connectable into the case to power the network switch without the need for external power cords connecting to the network switch to a power source.

7. The rack standard interchangeable network switch and patch panel of claim 6 wherein the at least one auxiliary power unit is slidable into the case from a removable panel disposed on a rear side of the case.

8. The rack standard interchangeable network switch and patch panel of claim 7 wherein the rear side of the case further comprises at least one removable panel for interconnection of at least one small form-factor pluggable module.

9. A rack standard interchangeable network switch and patch panel comprising:
a case member slidably connectable to a rack along a pair of lateral flange portions, said case member having an open front;
a network switch module insertable into the open front, said network switch module comprising:
an anterior portion having a touchscreen, said anterior portion configured to close the case member open front when the network switch module is inserted into the case member;
at least one latch member disposed upon the anterior portion, said at least one latch member moveable between a first position and a second position;
at least one power socket input operationally coupled with the at least one latch member wherein movement of the at least one latch member to the second position extends the at least one power socket input out of an opening disposed in a side of the case member for mating engagement of the at least one power socket input with a power supply unit installable in the rack;
at least one data connector operationally coupled with the at least one latch member wherein movement of the at least one latch member to the second position extends the data connector out the opening in the side of the case member for connection into a network connection socket disposed in the rack or in the power supply unit;
an auxiliary power supply unit slidably insertable into the case member via an opening in a rear of the case member;
a small-factor pluggable module slidingly insertable into the case member via a second opening in the rear of the case member;
a patch panel module insertable into the open front in lieu of and in the alternative to the network switch module, said patch panel comprising:
an anterior portion configured to close the open front whereby the patch panel module is securable into the case member when at least one quick release member is moved from a first position to a second position;
wherein the case member is secured to the rack when the at least one latch member of the network switch module or the quick release mechanism of the patch panel module is moved from the first to the second position whereby the case member is securable in rack position without the need of screws or other fasteners and the network switch module or patch panel module are installable without the need of removing the case member from configuration in the rack.

10. The rack standard interchangeable network switch and patch panel of claim 9 wherein inserting the patch panel module interconnects the patch panel module with circuitry disposed in operational communication with at least one connection port disposed on the rear side of the case member.

11. The rack standard interchangeable network switch and patch panel of claim 10 wherein the at least one connection port is configured for use with at least one cable connector set forth in U.S. patent application Ser. No. 18/168,412.
